(19) United States
(12) Patent Application Publication
(10) Pub. No.: US 2017/0033097 A1
(43) Pub. Date: Feb. 2, 2017

(54) ELECTROSTATIC DISCHARGE PROTECTION DEVICE AND METHOD OF MANUFACTURING THE SAME

(71) Applicant: Murata Manufacturing Co., Ltd., Nagaokakyo-shi (JP)

(72) Inventors: Takahiro SUMI, Nagaokakyo-shi (JP); Jun ADACHI, Nagaokakyo-shi (JP); Takayuki TSUKIZAWA, Nagaokakyo-shi (JP); Katsumi YASUNAKA, Nagaokakyo-shi (JP); Sumiyo NAKAMURA, Nagaokakyo-shi (JP); Mayu SUZUKI, Nagaokakyo-shi (JP)

(21) Appl. No.: 15/290,089

(22) Filed: Oct. 11, 2016

Related U.S. Application Data
(63) Continuation of application No. PCT/JP2015/066297, filed on Jun. 5, 2015.

(30) Foreign Application Priority Data
Jun. 13, 2014 (JP) 2014-122589

(51) Int. Cl. H01L 27/02; H01L 21/283; H01L 21/02; H01L 49/02

(52) U.S. Cl. CPC H01L 27/0288; H01L 28/60; H01L 21/283; H01L 21/02529

(57) ABSTRACT

An ESD protection device includes an insulative substrate, first and second discharge electrodes contacting the insulative substrate, the first and second discharge electrodes being spaced apart from and opposed to each other, first and second outer electrodes provided on an outside surface of the insulative substrate and electrically connected to the first and second discharge electrodes, respectively; and a discharge auxiliary electrode extending from the first discharge electrode to the second discharge electrode in a region where the first and second discharge electrodes oppose each other. The discharge auxiliary electrode includes semiconductor particles and metal particles having an average particle diameter of about 0.3 μm to about 1.5 μm, and a density of the metal particles at a random cross-section of the discharge auxiliary electrode is greater than or equal to about 20 particles/50 μm².

### CROSS REFERENCE TO RELATED APPLICATIONS

This application claims the benefit of priority to Japanese Patent Application 2014-122589 filed Jun. 13, 2014 and is a Continuation Application of PCT/JP2015/066297 filed on Jun. 5, 2015. The entire contents of these applications are hereby incorporated by reference herein.

### BACKGROUND OF THE INVENTION

1. Field of the Invention

The present invention relates to an electrostatic discharge protection device that protects an electronic device from damage caused by electrostatic discharge, and to a method of manufacturing the same.

2. Description of the Related Art

Electrostatic discharge protection devices (ESD protection devices) are used to prevent damage, erroneous operations, and other malfunctions in electronic devices caused by electrostatic discharge (ESD).

For example, International Publication No. WO 2008/146514 discloses an ESD protection device including a multilayer ceramic substrate, a hollow cavity portion provided within the multilayer ceramic substrate, at least one pair of discharge electrodes including opposing portions arranged so that tip portions thereof oppose each other with an interval therebetween within the hollow cavity portion, and an outer electrode that is provided on a surface of the multilayer ceramic substrate and is connected to the discharge electrodes. According to the ESD protection device disclosed in International Publication No. WO 2008/146514, the multilayer ceramic substrate includes a mixed portion including a metal material and a ceramic material, the mixed portion being disposed near the surface where the discharge electrodes are provided and adjacent to at least an opposing portion and a portion that is between the opposing portions of the discharge electrodes. The content of the metal material in the mixed portion is greater than or equal to 10 vol % and less than or equal to 50 vol %. With the above-described configuration, the ESD protection device disclosed in International Publication No. WO 2008/146514 can accurately set a discharge start voltage.

International Publication No. WO 2013/011821 discloses an ESD protection device including first and second discharge electrodes disposed so as to oppose each other, a discharge auxiliary electrode that extends across the first and second discharge electrodes, and an insulative substrate that secures the first and second discharge electrodes along with the discharge auxiliary electrode. In the ESD protection device disclosed in International Publication No. WO 2013/011821, the discharge auxiliary electrode includes a combination of a plurality of metal particles having a core-shell structure including a core portion that includes a first metal as its primary component and a shell portion that includes a metal oxide including a second metal as its primary component. With the above-described configuration, the ESD protection device disclosed in International Publication No. WO 2013/011821 provides high insulation reliability and favorable discharge characteristics.

Japanese Unexamined Patent Application Publication No. 2008-85284 discloses an overvoltage protection element including a first electrode, a second electrode, and a porous structure, connected between the first electrode and the second electrode, that is produced by performing a firing process using materials of the overvoltage protection element, which include a non-conductive powder, a metal conductive powder, and a bonding agent. Using the above-described materials of the overvoltage protection element when manufacturing the overvoltage protection element disclosed in Japanese Unexamined Patent Application Publication No. 2008-85284 makes it possible to suppress damage caused by discharged energy, which in turn makes it possible to extend the usage lifespan of the element.

Recently, as electronic devices continue to have higher levels of performance, there is a demand for lower discharge start voltages in ESD protection devices for the purpose of more surely preventing damage, erroneous operations, and other malfunctions in electronic devices caused by electrostatic discharge. On the other hand, there is also a demand for an ESD protection device to have insulative properties (initial insulative properties) high enough to suppress the occurrence of a short-circuit in normal usage situations.

### SUMMARY OF THE INVENTION

Preferred embodiments of the present invention provide an electrostatic discharge protection device having favorable initial insulative properties and a favorable operation rate at a comparatively low discharge voltage of about 2 kV.

The inventors of preferred embodiments of the present invention performed research focusing on the composition of the discharge auxiliary electrode that extends between two discharge electrodes disposed separated from each other and opposing each other in an ESD protection device. As a result, the inventors of preferred embodiments of the present invention discovered that using a discharge auxiliary electrode including semiconductor particles and metal particles, and setting the average particle diameter and density of the metal particles within the discharge auxiliary electrode to be within a specific numerical range, makes it possible to achieve favorable initial insulative properties and favorable operation rate at about 2 kV, which lead to the completion of preferred embodiments of the present invention.

According to a first preferred embodiment of the present invention, an electrostatic discharge protection device includes an insulative substrate; first and second discharge electrodes disposed in contact with the insulative substrate, the first and second discharge electrodes being spaced apart from and opposing each other; first and second outer electrodes provided on an outside surface of the insulative substrate, the first outer electrode being electrically connected to the first discharge electrode and the second outer electrode being electrically connected to the second discharge electrode; and a discharge auxiliary electrode extending from the first discharge electrode to the second discharge electrode in a region where the first and second discharge electrodes oppose each other; wherein the discharge auxiliary electrode includes at least semiconductor particles and metal particles, with an average particle diameter of the metal particles being about 0.3 μm to about 1.5 μm and a density of the metal particles at a random cross-section of the discharge auxiliary electrode being greater than or equal to about 20 particles/50 μm².

According to a second preferred embodiment of the present invention, a method of manufacturing an electrostatic discharge protection device includes a step (a) of forming an unfired discharge auxiliary electrode by applying a discharge auxiliary electrode paste including metal particles, semiconductor particles, and an organic vehicle to one main surface of a first ceramic green sheet, an average particle diameter of the metal particles being about 0.10 μm to about 1.00 μm and a volume fraction of the metal particles relative to all non-combustible components including the metal particles and the semiconductor particles being about 15 vol % to about 40 vol %; a step (b) of forming first and second unfired discharge electrodes by applying a discharge electrode paste on the first ceramic green sheet to which the discharge auxiliary electrode paste has been applied, the first and second unfired discharge electrodes being at least partially disposed on the unfired discharge auxiliary electrode and being spaced apart from and opposing each other on the unfired discharge auxiliary electrode; a step (c) of applying a hollow cavity portion formation paste on the first ceramic green sheet to which the discharge auxiliary electrode paste and the discharge electrode paste have been applied, the hollow cavity portion formation paste being applied so as to cover at least a region where the first and second unfired discharge electrodes oppose each other; a step (d) of forming an unfired multilayer body by stacking a second ceramic green sheet on the first ceramic green sheet to which the discharge auxiliary electrode paste, the discharge electrode paste, and the hollow cavity portion formation paste have been applied and shaping the ceramic green sheets to predetermined dimensions; a step (e) of firing the unfired multilayer body to obtain a multilayer body including the ceramic substrate, the first and second discharge electrodes, the discharge auxiliary electrode, and the hollow cavity portion; a step (f) of forming first and second unfired outer electrodes by applying an outer electrode paste to an outside surface of the fired multilayer body, the first unfired outer electrode being formed in contact with the first discharge electrode and the second unfired outer electrode being formed in contact with the second discharge electrode; and a step (g) of forming first and second outer electrodes by subjecting the unfired first and second outer electrodes to a baking process.

With the above-described configuration, the electrostatic discharge protection device according to a preferred embodiment of the present invention has favorable initial insulative properties and has a favorable operation rate at a comparatively low discharge voltage of about 2 kV. Additionally, with the above-described configuration, the method of manufacturing an electrostatic discharge protection device according to a preferred embodiment of the present invention produces an electrostatic discharge protection device having favorable initial insulative properties and having a favorable operation rate at a comparatively low discharge voltage of about 2 kV.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of the configuration of an ESD protection device according to a first preferred embodiment of the present invention.

FIG. 2 is a schematic plan view illustrating the arrangement of discharge electrodes in the ESD protection device according to the first preferred embodiment of the present invention.

FIG. 3 is a schematic plan view illustrating a first variation on the arrangement of discharge electrodes in the ESD protection device according to the first preferred embodiment of the present invention.

FIG. 4 is a cross-sectional view illustrating a second variation on the arrangement of discharge electrodes in the ESD protection device according to the first preferred embodiment of the present invention.

FIG. 5 is a cross-sectional view of the configuration of an ESD protection device according to a second preferred embodiment of the present invention of the present invention.

FIG. 6 is a cross-sectional view illustrating a first variation on the configuration of the ESD protection device according to the second preferred embodiment of the present invention.

FIG. 7 is a cross-sectional view illustrating a second variation on the configuration of the ESD protection device according to the second preferred embodiment of the present invention.

FIG. 8 is an overall cross-sectional view illustrating a third variation on the configuration of the ESD protection device according to the second preferred embodiment of the present invention.

### DETAILED DESCRIPTION OF THE PREFERRED EMBODIMENTS

Hereinafter, preferred embodiments of the present invention will be described with reference to the drawings. However, the preferred embodiments described hereinafter are for exemplary purposes only, and the present invention is not limited to the following preferred embodiments. The dimensions, materials, shapes, relative positions, and other parameters of the constituent elements described hereinafter are, unless otherwise specified, merely examples for descriptive purposes, and the scope of the present invention is not limited only thereto. Furthermore, the sizes, shapes, positional relationships, and other parameters of the elements illustrated in the drawings may be exaggerated to clarify the description thereof.

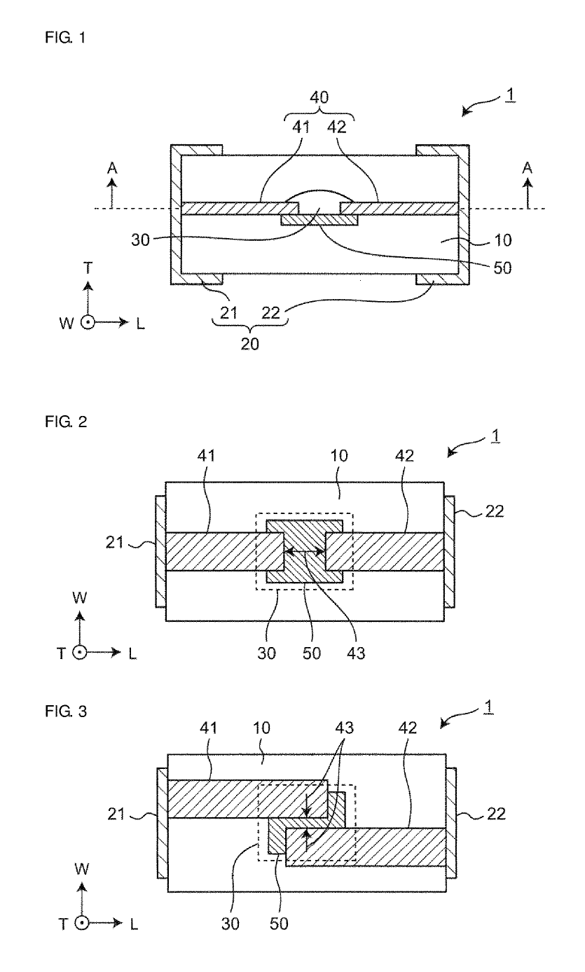

FIG. 1 is a cross-sectional view illustrating the configuration of an electrostatic discharge (ESD) protection device 1 according to a preferred embodiment of the present invention. The ESD protection device 1 illustrated in FIG. 1 includes an insulative substrate 10; a first discharge electrode and a second discharge electrode 42 (sometimes collectively referred to as discharge electrodes 40) disposed in contact with the insulative substrate 10; a first outer electrode 21 and a second outer electrode 22 (sometimes collectively referred to as outer electrodes 20) provided on an outside surface of the insulative substrate 10; and a discharge auxiliary electrode 50 extending across the first discharge electrode 41 and the second discharge electrode 42 in a region where the first discharge electrode 41 and the second discharge electrode 42 oppose each other.

In an ESD protection device according to a preferred embodiment of the present invention, a mechanism enabling favorable initial insulative properties and a favorable operation rate at a comparatively low discharge voltage (about 2 kV, for example) to be achieved is not restricted to any particular theory, and can generally be thought of as follows. When a high voltage exceeding a discharge start voltage is applied to the ESD protection device 1 illustrated in FIG. 1, a gaseous discharge and a surface discharge occur at an area where the discharge electrodes oppose each other. The discharge auxiliary electrode 50 has a function of inducing the surface discharge. A discharge start voltage produced by a surface discharge normally tends to be lower than a discharge start voltage produced by a gaseous discharge. Accordingly, by providing the discharge auxiliary electrode 50, it is possible to lower the discharge start voltage.

In an ESD protection device according to a preferred embodiment of the present invention, the discharge auxiliary electrode preferably includes semiconductor particles in addition to metal particles and, thus, is insulative as a whole. The occurrence of short circuiting caused by metal particles making contact with each other is, therefore, effectively reduced or prevented, which makes it possible to achieve favorable initial insulative properties.

Furthermore, the smaller the metal particles in the discharge auxiliary electrode are, the easier it is for an electric field to be concentrated between end portions of the discharge electrodes and the metal particles in the discharge auxiliary electrode, which tends to increase the electric field that is produced. The metal particles included in the discharge auxiliary electrode according to a preferred embodiment of the present invention are extremely fine particles preferably having an average particle diameter of about 0.3 μm to about 1.5 μm, for example, and thus, a greater electric field is produced. Additionally, as the amount of metal particles included in the discharge auxiliary electrode increases, so does the number of points or locations that produce an electric field (electric field points). In a discharge auxiliary electrode according to a preferred embodiment of the present invention, the density of the metal particles in a given cross-section is preferably greater than or equal to about 20 particles/50 μm², for example, and thus, many metal particles are present. This makes it possible to produce many electric field points. According to the present preferred embodiment, it is thought that leader streamers (electron avalanches) are generated at the end portion of one of the discharge electrodes (the first discharge electrode, for example) due to the above-described electric field concentration. A discharge auxiliary electrode according to a preferred embodiment of the present invention includes many metal particles, and thus, a large amount of leader streamers are generated. This makes it possible to ensure that the leader streamers reach the other discharge electrode (the second discharge electrode, for example) without losing speed. As a result, an ESD protection device according to a preferred embodiment of the present invention effectively produces a surface discharge between the discharge electrodes, which makes it possible to achieve a favorable operation rate at a comparatively low discharge voltage (about 2 kV, for example).

Furthermore, where a gas present in the region between the discharge electrodes is a gas that ionizes easily, such as a noble gas, the gas molecules ionize more easily, such that a large amount of gas ions are produced. As a result, a surface discharge is produced even more effectively between the discharge electrodes, which improves the operation rate at a comparatively low discharge voltage (about 2 kV, for example) to an even greater extent.

### First Preferred Embodiment

FIG. 1 is a cross-sectional view illustrating an electrostatic discharge protection device (ESD protection device) according to a first preferred embodiment of the present invention. The ESD protection device 1 illustrated in FIG. 1 includes the insulative substrate 10, the first discharge electrode 41 and the second discharge electrode 42 disposed in contact with the insulative substrate 10, the first outer electrode 21 and the second outer electrode 22 provided on an outside surface of the insulative substrate 10, and the discharge auxiliary electrode 50 extending across the first discharge electrode 41 and the second discharge electrode 42 in a region where the first discharge electrode 41 and the second discharge electrode 42 oppose each other. The ESD protection device 1 according to the present preferred embodiment further includes a hollow cavity portion 30. As indicated in FIG. 1, in the present specification, a direction parallel to a direction in which the first and second discharge electrodes substantially extend is called a length direction (L direction), a direction perpendicular to the length direction in a horizontal plane is called a width direction (W direction), and a direction perpendicular to both the length direction and the width direction is called a thickness direction (T direction). A plane perpendicular to the L direction is a WT plane, a plane perpendicular to the W direction is an LT plane, and a plane perpendicular to the T direction is a LW plane.

The insulative substrate 10 is not particularly limited as long as the substrate is insulative, and may preferably be a ceramic substrate, for example. Any ceramic material generally used for ceramic substrates can be used as appropriate when the insulative substrate 10 is a ceramic substrate, but the present invention is not limited thereto. For example, a ceramic material including Ba, Al, and Si as primary components (BAS), Low Temperature Cofirable Ceramics (LTCC), such as glass ceramics, magnetic ceramics, or other ceramics can be used as the insulative substrate (ceramic substrate) 10. In the present preferred embodiment, the insulative substrate 10 includes a substrate on an upper side of the hollow cavity portion 30 and a substrate on a lower side of the hollow cavity portion 30. The substrate on the upper side of the hollow cavity portion 30 and the substrate on the lower side of the hollow cavity portion 30 may each include a single layer or may include a plurality of layers. Where the substrate on the upper side of the hollow cavity portion 30 and/or the substrate on the lower side of the hollow cavity portion 30 include a plurality of layers, the respective layers may have the same compositions, or may have different compositions. Additionally, in the present preferred embodiment, an insulative substrate made from a resin or other suitable material (a resin substrate) may be used as the insulative substrate 10, instead of a ceramic substrate.

The first discharge electrode 41 and the second discharge electrode 42 are disposed in contact with the insulative substrate 10. In the present preferred embodiment, the first discharge electrode 41 and the second discharge electrode 42 are disposed within the insulative substrate 10. The first discharge electrode 41 and the second discharge electrode 42 are spaced apart from and opposed to each other. In the present preferred embodiment, the first discharge electrode 41 and the second discharge electrode 42 are spaced apart from and opposed to each other in the hollow cavity portion 30 provided within the insulative substrate 10. In the ESD protection device 1 illustrated in FIG. 1, the first discharge electrode 41 and the second discharge electrode 42 are preferably disposed so that end portions on the sides thereof that oppose each other are arranged along an inner side of the hollow cavity portion 30. Although the present specification describes the ESD protection device 1, which includes the pair of discharge electrodes 40 including the first discharge electrode 41 and the second discharge electrode 42, as an example, the ESD protection device according to the present preferred embodiment may include two or more pairs of discharge electrodes. Where the ESD protection device according to the present preferred embodiment includes two or more pairs of discharge electrodes, additional hollow cavity portions and discharge auxiliary electrodes can be provided as appropriate corresponding to the respective discharge electrode pairs.

FIG. 2 is a cross-sectional view of the ESD protection device 1 taken from an A-A line in FIG. 1, and schematically illustrates an example of the arrangement of the discharge electrodes in an ESD protection device according to a preferred embodiment of the present invention. In the arrangement illustrated in FIG. 2, the first discharge electrode 41 and the second discharge electrode 42 are disposed so that end surfaces thereof are spaced apart from and opposed to each other. In the present specification, a “distance between discharge electrodes” refers to a minimum distance between the first discharge electrode and the second discharge electrode in a plane where the discharge electrodes and the discharge auxiliary electrode make contact. In the arrangement illustrated in FIG. 2, a distance between discharge electrodes 43 refers to a distance between the end surface of the first discharge electrode 41 and the end surface of the second discharge electrode 42 that oppose each other. However, the arrangement of the discharge electrodes in the ESD protection device according to the present preferred embodiment is not limited to the arrangement illustrated in FIGS. 1 and 2, and can be changed as appropriate depending on the application.

FIG. 3 illustrates a first variation on the arrangement of the discharge electrodes in the ESD protection device according to a preferred embodiment of the present invention. Similarly to FIG. 2, FIG. 3 schematically illustrates the arrangement of the discharge electrodes in a cross-section perpendicular to the thickness direction (that is, in the LW plane). In the arrangement illustrated in FIG. 3, the first discharge electrode 41 and the second discharge electrode 42 are arranged parallel or substantially parallel to each other in the LW plane, with a portion of one side surface of the first discharge electrode 41 and a portion of one side surface of the second discharge electrode 42 spaced apart from and opposed to each other. In the arrangement illustrated in FIG. 3, the distance between discharge electrodes 43 refers to a distance between the side surface of the first discharge electrode 41 and the side surface of the second discharge electrode 42 at portions that oppose each other.

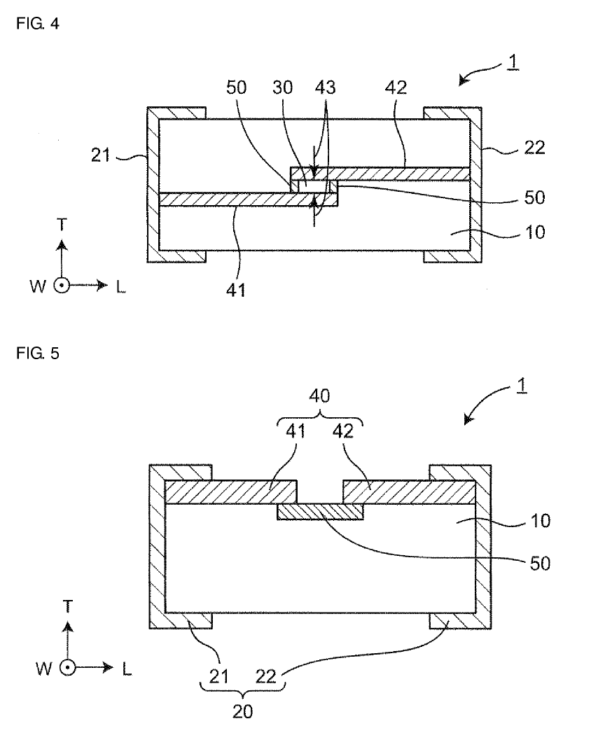

FIG. 4 illustrates a second variation on the arrangement of the discharge electrodes in the ESD protection device according to a preferred embodiment of the preset invention. Similarly to FIG. 1, FIG. 4 schematically illustrates the arrangement of the discharge electrodes in a cross-section perpendicular to the width direction (that is, in the LT plane). In the arrangement illustrated in FIG. 4, the first discharge electrode 41 and the second discharge electrode 42 are arranged parallel or substantially parallel to each other in the LT plane, with a portion of a top surface of the first discharge electrode 41 and a portion of a bottom surface of the second discharge electrode 42 spaced apart from and opposed to each other. In the arrangement illustrated in FIG. 4, the distance between discharge electrodes refers to a distance between the top surface of the first discharge electrode 41 and the bottom surface of the second discharge electrode 42 at the portions of the discharge electrodes that oppose each other.

It is preferable that the distance between discharge electrodes 43 at the region where the first discharge electrode 41 and the second discharge electrode 42 oppose each other be about 10 μm to about 50 μm, for example. The distance between discharge electrodes 43 being greater than or equal to about 10 μm makes it possible to use a discharge electrode paste when such a discharge electrode paste is used for screen printing, as will be described later. The distance between discharge electrodes 43 being less than or equal to about 50 μm makes it possible to further improve a discharge rate at about 2 kV, for example. Thus, setting the distance between discharge electrodes to be within the above-described range makes it possible to obtain an ESD protection element having favorable ESD protection characteristics.

Although the compositions of the first discharge electrode 41 and the second discharge electrode 42 are not particularly limited, the electrodes may preferably include Cu, Ni, Ag, Pd, an alloy thereof, or a combination of these, for example.

The hollow cavity portion 30 is provided within the insulative substrate 10. The dimensions and shape of the hollow cavity portion 30 are not particularly limited as long as the first discharge electrode 41 and the second discharge electrode 42 are disposed within the hollow cavity portion 30 so as to be spaced apart from and opposed to each other. For example, in addition to a shape illustrated in FIG. 1, in which an upper portion of the hollow cavity portion is curved, a shape such as a rectangle, a cylinder, or other suitable shapes can be selected as appropriate.

It is preferable that the hollow cavity portion 30 includes a noble gas, such as Ne, Ar, or other noble gas, for example. A noble gas ionizes easily, and thus, a greater amount of gas ions is able to be produced. As a result, a surface discharge is able to be even more effectively produced, which makes it possible to improve the operation rate at a comparatively low discharge voltage (about 2 kV, for example) to a greater extent. It is more preferable that the hollow cavity portion 30 includes Ar as the noble gas. Among noble gases, Ar ionizes comparatively more easily and cheaply as compared to other noble gases, which makes it possible to obtain an ESD protection device having favorable ESD protection characteristics at a lower cost. The abundance of noble gas in the hollow cavity portion 30 can be adjusted as appropriate to an amount that enables surface discharges to be induced effectively.

The first outer electrode 21 and the second outer electrode 22 are provided on an outside surface of the insulative substrate 10. The first outer electrode 21 is electrically connected to the first discharge electrode 41, and the second outer electrode 22 is electrically connected to the second discharge electrode 42. Although the compositions of the first outer electrode 21 and the second outer electrode 22 are not particularly limited, the electrodes may preferably include Cu, Ag, Pd, Ni, an alloy thereof, or a combination of these, for example. The metal material may be in particle form, and the particles may be spherical, flat, or a combination thereof, for example. In addition to the metal material, a glass material may be added to the first outer electrode 21 and the second outer electrode 22. A single type of glass material may be used, or a combination of glass materials having different softening points may be used.

The discharge auxiliary electrode 50 extends from the first discharge electrode 41 to the second discharge electrode 42 in a region where the first discharge electrode 41 and the second discharge electrode 42 are opposed to each other. The discharge auxiliary electrode 50 includes at least semiconductor particles and metal particles. The metal particles and the semiconductor particles are each dispersed throughout the discharge auxiliary electrode 50, and the discharge auxiliary electrode 50 as a whole is insulative. In the preferred embodiment illustrated in FIG. 1, the discharge auxiliary electrode 50 is preferably arranged along an inner surface of the hollow cavity portion 30, and makes partially contact with the first discharge electrode 41 and the second discharge electrode 42.

The metal particles included in the discharge auxiliary electrode 50 preferably have an average particle diameter of about 0.3 μm to about 1.5 μm, for example. As will be described later, an average particle diameter of greater than or equal to about 0.10 μm for the metal particles of the raw material allows for easier handling and is thus preferable. Although also depending on various conditions, using metal particles having an average particle diameter of greater than or equal to about 0.10 μm as the metal particles of the raw material normally makes it possible for the average particle diameter of the metal particles in the obtained ESD protection device to be greater than or equal to about 0.3 μm. An average particle diameter of less than or equal to about 1.5 μm makes it possible to achieve favorable initial insulative properties and an favorable operation rate at a comparatively low voltage (about 2 kV, for example). It is preferable that the average particle diameter of the metal particles be about 0.3 μm to about 0.66 μm, for example. An average particle diameter of less than or equal to about 0.66 μm makes it possible to further improve the initial insulative properties and operation rate at a comparatively low voltage (about 2 kV, for example). The average particle diameter of the metal particles in the discharge auxiliary electrode 50 can be determined by, for example, capturing a scanning electron microscope (SEM) image (reflection electron image) of a cross-section of the discharge auxiliary electrode, measuring the lengths of long sides of the metal particles in the obtained image for which the entire particle can be seen, and then calculating an average value of the measured lengths of the long sides.

The density of the metal particles in a random cross-section of the discharge auxiliary electrode 50 is preferably greater than or equal to about 20 particles/50 μm², for example. A density of greater than or equal to about 20 particles/50 μm² makes it possible to achieve an favorable operation rate at a comparatively low voltage (about 2 kV, for example). It is preferable that the density of the metal particles be about 55 to about 170 particles/50 μm², for example. A density of greater than or equal to about 55 particles/50 μm² makes it possible to achieve an even more favorable operation rate at a comparatively low voltage (about 2 kV, for example). Although a higher density of metal particles tends to improve the characteristics of the obtained ESD protection device, a density of less than or equal to about 170 metal particles/50 μm² is sufficient to achieve favorable initial insulative properties and an favorable operation rate at about 2 kV, for example. In the present specification, the density of the metal particles in a random cross-section of the discharge auxiliary electrode 50 can be determined by, for example, capturing an SEM image (reflection electron image) of a cross-section of the discharge auxiliary electrode 50 and, in the obtained image, counting the total number of metal particles present within a 50 μm² surface area range of the discharge auxiliary electrode 50. However, the density unit “particles/50 μm²” is not intended to limit the surface area of the range in which the total number of metal particles is counted to 50 μm². The density of the metal particles may be calculated based on the total number of metal particles counted within an arbitrary surface area range in an arbitrary cross-section of the discharge auxiliary electrode 50.

The metal particles included in the discharge auxiliary electrode 50 are not particularly limited, and may preferably be particles including at least one metal selected from a group consisting of Cu, Ag, Pd, Pt, Al, Ni, W, and Mo, and/or an alloy thereof, for example. A single type of metal particle may be used or a plurality of types of metal particles may be used in combination in the discharge auxiliary electrode 50. It is preferable that the metal particles be Cu particles. Cu is cheap, and also has a low work function, and therefore, effectively generate surface discharges. Accordingly, using Cu particles as the metal particles makes it possible to obtain an ESD protection device having superior ESD protection characteristics at a low cost. Note that in the present specification, the metal particles “being Cu particles”, for example, means that Cu is the primary component of the metal particles, and means that the metal particles have a Cu content of greater than or equal to about 90 wt %, for example. The constituent components of the metal particles can be determined through TEM-EDX (energy-dispersive X-ray spectroscopy), for example.

The semiconductor particles included in the discharge auxiliary electrode 50 are not particularly limited, and may, for example, preferably be at least one type of particle selected from a group consisting of metal semiconductors, such as Si and Ge, carbides, such as SiC, TiC, ZrC, Mo₂C, and WC, nitrides, such as TiN, ZrN, CrN, VN, and TaN, silicides, such as TiSi₂, ZrSi₂, WSi₂, MoSi₂, and CrSi₂, borides, such as TiB₂, ZrB₂, CrB, LaB₆, MoB, and WB, and oxides, such as ZnO and SrTiO₃. A single type of semiconductor particle may be used alone or a plurality of types of semiconductor particles may be used in combination in the discharge auxiliary electrode 50. It is preferable that the semiconductor particles be SiC particles, for example. SiC is cheap and has superior stability at high temperatures. Accordingly, using SiC particles as the semiconductor particles makes it possible to obtain, at a low cost, an ESD protection device having superior resistance to shorting when an ESD is applied. Additionally, where SiC particles are used as the semiconductor particles, the SiC particles are able to act as electron receptors and donors, and the discharge start voltage of the surface discharge can, thus, be even further reduced. An ESD protection device that further improves the operation rate at a comparatively low voltage (about 2 kV, for example) is obtained as a result. Note that in the present specification, the semiconductor particles “being SiC particles”, for example, means that SiC is the primary component of the semiconductor particles, and that the semiconductor particles preferably have a SiC content of greater than or equal to about 90 wt %, for example. The constituent components of the semiconductor particles can be determined through TEM-EDX, for example.

It is preferable that the discharge auxiliary electrode further include insulative particles. Where the discharge auxiliary electrode 50 includes insulative particles, sintering of the metal particles is significantly reduced or prevented during firing, which makes it possible to obtain an ESD protection device having a higher operation rate at a comparatively low voltage (about 2 kV, for example). Additionally, where the discharge auxiliary electrode 50 includes insulative particles, the sintering together of semiconductor particles is significantly reduced or prevented during firing, and the sintering together of semiconductor particles is also significantly reduced or prevented when an ESD is applied. This makes it possible to obtain an ESD protection device having a higher operation rate at a comparatively low voltage (about 2 kV, for example) and superior resistance to short circuiting when an ESD is applied.

The insulative particles are not particularly limited, and, for example, at least one type of particle selected from a group consisting of Al₂O₃, TiO₂, ZrO₂, SiO₂, and other suitable particle may be used. A single type of insulative particle may be used or a plurality of types of insulative particles may be used in combination in the discharge auxiliary electrode 50. The insulative particles may preferably be Al₂O₃ particles, for example. Al₂O₃ is cheap, and thus, the ESD protection device can be obtained at a low cost. Additionally, where the semiconductor particles are SiC particles and the metal particles are Cu particles, the Cu component will diffuse into an SiO₂ film present on the surface of the SiC particles, causing the viscosity of the SiO₂ film to be reduced, thus making it easier to sinter the Cu particles and/or the SiC particles during firing. On the other hand, where the discharge auxiliary electrode 50 includes Al₂O₃ particles as the insulative particles, the Cu component diffusing into the SiO₂ film present on the surface of the SiC particles is effectively reduced or prevented, which makes it possible to prevent the viscosity of the SiO₂ film from reducing. Sintering of the semiconductor particles (SiC particles) and/or the metal particles (Cu particles) is effectively reduced or prevented as a result, which makes it possible to obtain an ESD protection device having superior ESD protection characteristics. Note that in the present specification, the insulative particles “being Al₂O₃ particles”, for example, means that Al₂O₃ is the primary component of the insulative particles, and means that the insulative particles preferably have an Al₂O₃ content of greater than or equal to about 90 wt %, for example. The constituent components of the insulative particles can be determined through TEM-EDX (energy-dispersive X-ray spectroscopy), for example.

The constituent components of the discharge auxiliary electrode can be identified through microfocus X-ray analysis, for example.

### Second Preferred Embodiment

An ESD protection device according to a second preferred embodiment of the present invention will be described hereinafter with reference to FIG. 5. FIG. 5 is a cross-sectional view of the configuration of an ESD protection device 1 according to the second preferred embodiment of the present invention. The ESD protection device 1 illustrated in FIG. 5 includes the insulative substrate 10, the first discharge electrode 41 and the second discharge electrode 42 disposed in contact with the insulative substrate 10, the first outer electrode 21 and the second outer electrode 22 provided on an outside surface of the insulative substrate 10, and the discharge auxiliary electrode 50 extending from the first discharge electrode 41 to the second discharge electrode 42 in a region where the first discharge electrode 41 and the second discharge electrode 42 are opposed to each other. In the ESD protection device 1 according to the present preferred embodiment, the first discharge electrode 41 and the second discharge electrode 42 are disposed on an outside surface of the insulative substrate 10. The second preferred embodiment will be described hereinafter by focusing on the differences from the first preferred embodiment, and unless otherwise stated, the descriptions provided in the first preferred embodiment also apply.

In the present preferred embodiment, the discharge electrodes 40 are disposed on an outside surface of the insulative substrate 10. Similarly to the arrangement described in the first preferred embodiment and illustrated in FIG. 2, the first discharge electrode 41 and the second discharge electrode 42 are disposed in the ESD protection device 1 illustrated in FIG. 5 so that one end surface of the first discharge electrode 41 and one end surface of the second discharge electrode 42 are spaced apart from and opposed to each other. However, the arrangement of the discharge electrodes in the ESD protection device according to the present preferred embodiment is not limited to such an arrangement, and can be changed as appropriate depending on the application. For example, similarly to the arrangement described in the first preferred embodiment and illustrated in FIG. 3, the first discharge electrode 41 and the second discharge electrode 42 may be arranged so that the first discharge electrode 41 and the second discharge electrode 42 are parallel or substantially parallel to each other in the LW plane, with a portion of one side surface of the first discharge electrode 41 and a portion of one side surface of the second discharge electrode 42 being spaced apart from and opposed to each other. Although the present specification describes the ESD protection device 1, which includes the pair of discharge electrodes 40 including the first discharge electrode 41 and the second discharge electrode 42, as an example, the ESD protection device according to the present preferred embodiment may include two or more pairs of discharge electrodes. Where the ESD protection device according to the present preferred embodiment includes two or more pairs of discharge electrodes, additional discharge auxiliary electrodes may be provided as appropriate to correspond to the respective discharge electrode pairs. Furthermore, the ESD protection device according to a preferred embodiment of the present invention may have a configuration that combines at least one pair of discharge electrodes disposed within the insulative substrate with at least one pair of discharge electrodes disposed on an outside surface of the insulative substrate.

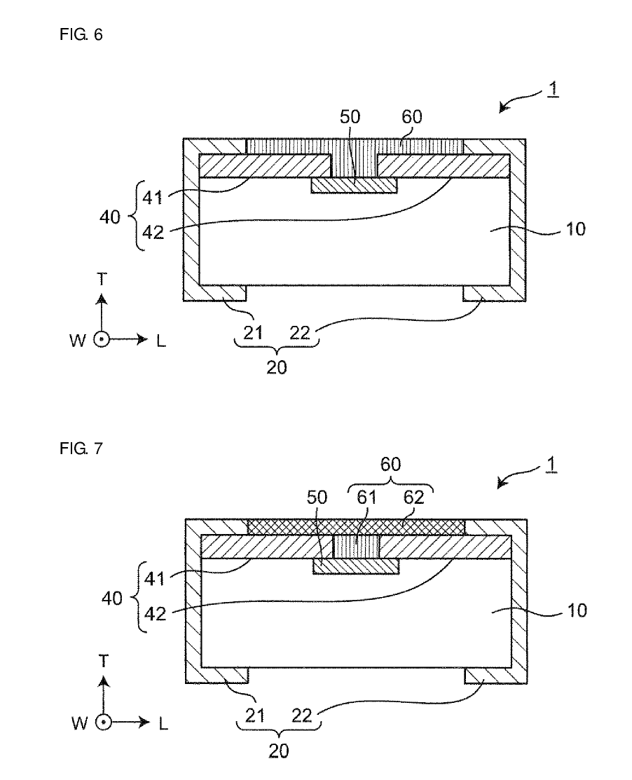

A first variation on the ESD protection device according to a preferred embodiment of the present invention is illustrated in FIG. 6. As illustrated in FIG. 6, the ESD protection device 1 may preferably further include a resin layer 60 disposed on the first discharge electrode 41, the second discharge electrode 42, and the discharge auxiliary electrode 50. The resin layer 60 improves the reliability of the ESD protection device 1 by preventing degradation, such as oxidization of the discharge electrodes 40 and/or the discharge auxiliary electrode 50 due to the influence of the surrounding environment.

The resin layer 60 may preferably include a single layer as illustrated in FIG. 6, but may also include two or more different layers. FIG. 7 illustrates a second variation on the ESD protection device according to a preferred embodiment of the present invention. In this variation, the resin layer 60 preferably includes a first resin layer 61 and a second resin layer 62. The first resin layer 61 is disposed in a region where the first discharge electrode 41 and the second discharge electrode 42 oppose each other, and the second resin layer 62 is disposed upon the first resin layer 61.

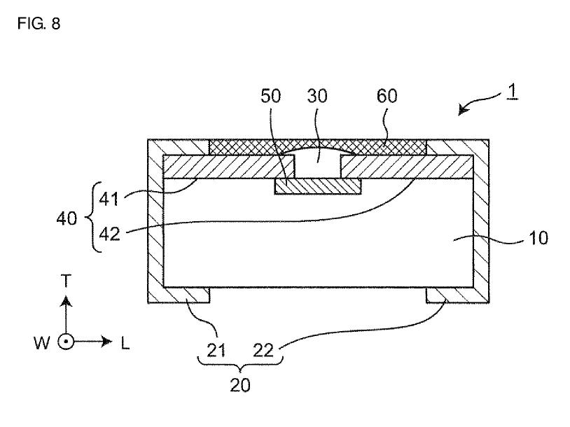

FIG. 8 illustrates a third variation on the ESD protection device according to a preferred embodiment of the present invention. The ESD protection device 1 illustrated in FIG. 8 preferably further includes the resin layer 60 disposed upon the first discharge electrode 41 and the second discharge electrode 42, and the hollow cavity portion 30 provided within the resin layer 60, the first discharge electrode 41 and the second discharge electrode 42 are spaced apart from and opposed to each other within the hollow cavity portion 30. The dimensions and shape of the hollow cavity portion 30 are not particularly limited as long as the first discharge electrode 41 and the second discharge electrode 42 are disposed within the hollow cavity portion 30 so as to be spaced apart from and opposed to each other. For example, in addition to a shape such as that illustrated in FIG. 8, in which an upper portion of the hollow cavity portion is curved, a shape such as a rectangle, a cylinder, or other suitable shape can be selected as appropriate. It is preferable that the hollow cavity portion 30 includes a noble gas, such as Ne, Ar, or other noble gas. A noble gas ionizes easily, and thus, a greater amount of gas ions can be produced. A surface discharge can be even more effectively produced as a result, which improves the operation rate at a comparatively low discharge voltage (about 2 kV, for example) to a greater extent. It is further preferable that the hollow cavity portion 30 includes Ar as the noble gas. Among noble gases, Ar ionizes comparatively more easily and cheaply, which makes it possible to obtain an ESD protection device having favorable ESD protection characteristics at a lower cost.

A non-limiting example of a method of manufacturing the ESD protection device according to the first preferred embodiment of the present invention will be described hereinafter, but the present invention is not intended to be limited to the method described hereinafter. The method of manufacturing the ESD protection device according to the present preferred embodiment includes at least steps (a) to (g) described hereinafter.

### Step (a)

Step (a) is a step of forming an unfired discharge auxiliary electrode by applying a discharge auxiliary electrode paste including metal particles, semiconductor particles, and an organic vehicle to one main surface of a first ceramic green sheet.

### Preparation of Ceramic Green Sheet

A ceramic green sheet for forming a ceramic substrate is prepared through the following procedure. A ceramic material is mixed with an organic carrier, such as toluene or Ekinen; a binder, plasticizer, and other suitable ingredients are added to the mixture, which is then mixed further to obtain a slurry. This slurry is shaped using a doctor blade method or other suitable method to obtain a ceramic green sheet having a predetermined thickness. A ceramic material including Ba, Al, and Si as primary components (BAS) can preferably be used as the ceramic material, for example.

### Preparation of Discharge Auxiliary Electrode Paste

The discharge auxiliary electrode paste for forming the discharge auxiliary electrode is prepared through the following procedure. The discharge auxiliary electrode paste is prepared by blending semiconductor particles, metal particles, an organic vehicle obtained by dissolving a binder, such as ethyl cellulose, in an organic carrier, such as terpineol, and depending on the case a dispersant for the semiconductor particles and the metal particles at a predetermined ratio, and then mixing using a three-roll mill or other suitable mixer.

The metal particles used in the discharge auxiliary electrode paste (also called “raw material metal particles”) preferably have an average particle diameter of about 0.10 μm to about 1.00 μm, for example. An average particle diameter of greater than or equal to about 0.10 μm enables easier handling, and also makes it possible to effectively reduce or prevent oxidization, which is undesirable for metal particles. An average particle diameter of less than or equal to about 1.00 μm enables the average particle diameter and the density of the metal particles included in the discharge auxiliary electrode of the obtained ESD protection device to be within the above-described suitable numerical value range, so as to obtain an ESD protection device having superior ESD protection characteristics. Note that the average particle diameter of the metal particles included in the discharge auxiliary electrode of the obtained ESD protection device tends to increase as the average particle diameter of the raw material metal elements increases. The average particle diameter of the raw material metal particles can be determined by, for example, capturing an SEM image of the metal particles, drawing a single diagonal line from an apex of the obtained image, measuring the length of a long side of all metal particles intersecting with the diagonal line, and calculating an average value of the measured lengths of the long sides.

The volume fraction of metal particles relative to all non-combustible components included in the discharge auxiliary electrode paste is preferably about 15 vol % to about 40 vol %, for example. In the present specification, “non-combustible components” refers to, of the components included in the discharge auxiliary electrode paste, components that are not lost as gas through vaporization or combustion in the firing performed in step (e) and that, therefore, are included in the discharge auxiliary electrode in the obtained ESD protection device. For example, where the discharge auxiliary electrode paste includes only metal particles, semiconductor particles, and an organic vehicle, the “non-combustible components” are the metal particles and the semiconductor particles. Where the discharge auxiliary electrode paste includes insulative particles (described below) in addition to metal particles, semiconductor particles, and an organic vehicle, the “non-combustible components” are the metal particles, the semiconductor particles, and the insulative particles. The volume fraction of metal particles relative to all non-combustible components being greater than or equal to about 15 vol % enables an ESD protection device having a superior operation rate at a comparatively low voltage (about 2 kV, for example) to be obtained. The volume fraction of metal particles relative to all non-combustible components being less than or equal to about 40 vol % makes it possible to significantly reduce or prevent sintering between the metal particles in step (e), which enables an ESD protection device having superior ESD protection characteristics to be obtained. It is preferable that the volume fraction of metal particles relative to all non-combustible components be 30 to 40 vol %. A volume fraction of greater than or equal to about 30 vol % makes it possible to achieve an even more favorable operation rate for the ESD protection device at a comparatively low voltage (about 2 kV, for example).

The raw material metal particles are not particularly limited, and may preferably be particles including at least one metal selected from a group consisting of Cu, Ag, Pd, Pt, Al, Ni, W, Mo, and/or an alloy thereof, for example. A single type of metal particle may be used or a plurality of types of metal particles may be used in combination as the raw material metal particles. It is preferable that the raw material metal particles be Cu particles. When the raw material metal particles are Cu particles, it is possible to obtain an ESD protection device having superior ESD protection characteristics at a low cost. Note that in the present specification, the “raw material metal particles being Cu particles”, for example, means that Cu is the primary component of the raw material metal particles, and specifically means that the raw material metal particles preferably have a Cu content of greater than or equal to about 90 wt %, for example. The composition of the raw material metal particles can be identified through, for example, ICP-AES (inductively coupled plasma atomic emission spectroscopy) and inert gas fusion using an oxygen/nitrogen analyzer.

It is preferable that the specific surface area of the semiconductor particles used in the discharge auxiliary electrode paste (also called “raw material semiconductor particles”) be greater than or equal to about 3 m²/g, for example. The specific surface area being greater than or equal to about 3 m²/g makes it possible for the obtained ESD protection device to even more effectively generate a surface discharge, which in turn makes it possible to improve the operation rate of the ESD protection device at a comparatively low voltage (about 2 kV, for example). It is further preferable that the specific surface area of the raw material semiconductor particles be about 7 m²/g to about 15 m²/g, for example. Setting the specific surface area to be greater than or equal to about m²/g reduces variations in the ESD protection characteristics. Setting the specific surface area to be less than or equal to about 15 m²/g facilitates dispersing the raw material semiconductor particles uniformly throughout the discharge auxiliary electrode paste, which makes it possible to effectively reduce or prevent variations in the ESD protection characteristics. The specific surface area of the semiconductor particles can be measured through, for example, singlepoint BET using nitrogen gas.

It is preferable that the raw material semiconductor particles be a pulverized product, for example. Where the semiconductor particles are a pulverized product, the semiconductor particles have irregular shapes, with the surfaces of the particles having partially tapered shapes. The semiconductor particles having irregular shapes make it easier for electrons to be released from the surfaces of the semiconductor particles, so as to more effectively produce a surface discharge. Accordingly, when the semiconductor particles are a pulverized product, an ESD protection device that further improves the operation rate at a comparatively low discharge voltage (about 2 kV, for example) is obtained.

The raw material semiconductor particles are not particularly limited, and may, for example, be at least one type of particle selected from a group consisting of metal semiconductors such as Si and Ge, carbides, such as SiC, TiC, ZrC, Mo₂C, and WC, nitrides, such as TiN, ZrN, CrN, VN, and TaN, silicides, such as TiSi₂, ZrSi₂, WSi₂, MoSi₂, and CrSi₂, borides, such as TiB₂, ZrB₂, CrB, LaB₆, MoB, and WB, and oxides, such as ZnO and SrTiO₃. A single type of semiconductor particle may be used or a plurality of types of semiconductor particles may be used in combination as the raw material semiconductor particles. It is preferable that the raw material semiconductor particles be SiC particles, for example. Using SiC particles as the semiconductor particles further improves the operation rate at a comparatively low voltage (about 2 kV, for example), and makes it possible to obtain, at a low cost, an ESD protection device having superior resistance to short circuiting when an ESD is applied. Note that in the present specification, the “raw material semiconductor particles being SiC particles”, for example, means that SiC is the primary component of the raw material semiconductor particles, and specifically means that the raw material semiconductor particles preferably have a SiC content of greater than or equal to about 90 wt %, for example. The composition of the raw material semiconductor particles can be identified through a combination of qualitative analysis using an XRD (X-ray diffractometer), and ICP-AES and oxygen flow combustion high-frequency furnace-based infrared absorption using a carbon/sulfur analyzer, for example.

It is preferable that the discharge auxiliary electrode paste further includes insulative particles (also called “raw material insulative particles”). Where the discharge auxiliary electrode paste includes insulative particles, sintering of the metal particles is effectively reduced or prevented during the firing of step (e), so as to obtain an ESD protection device having a higher operation rate at a comparatively low voltage (about 2 kV, for example). Additionally, where the discharge auxiliary electrode paste includes insulative particles, sintering of the semiconductor particles during the firing of step (e) is effectively reduced or prevented, and sintering of the semiconductor particles during ESD application is significantly reduced or prevented in the obtained ESD protection device. Accordingly, where the discharge auxiliary electrode paste includes insulative particles, an ESD protection device is obtained that has a higher operation rate at a comparatively low voltage (about 2 kV, for example) and that has superior resistance to short circuiting when an ESD is applied. Note that even where the discharge auxiliary electrode paste further includes insulative particles, it is preferable that the stated volume fraction of metal particles relative to all non-combustible components including metal particles, semiconductor particles, and insulative particles be about 15 vol % to about 40 vol %, for example.

It is preferable that the specific surface area of the raw material insulative particles be greater than or equal to about 20 m²/g, for example. Setting the specific surface area to greater than or equal to about 20 m²/g even more effectively reduces or prevents sintering of the metal particles and the semiconductor particles, and makes it possible to achieve this effect even where a small amount of insulative particles is added. It is further preferable that the specific surface area of the raw material insulative particles be about 30 m²/g to about 60 m²/g, for example. Setting the specific surface area to greater than or equal to about 30 m²/g enables further reduction or prevention of sintering of the metal particles and the semiconductor particles, due to a small amount being added. Setting the specific surface area to be less than or equal to about 60 m²/g makes it easy to disperse the raw material insulative particles uniformly throughout the discharge auxiliary electrode paste, which makes it possible to more effectively reduce or prevent variations in the ESD protection characteristics. The specific surface area of the insulative particles can be measured through, for example, singlepoint BET using nitrogen gas.

The raw material insulative particles may preferably be at least one type of particle selected from a group consisting of Al₂O₃, TiO₂, ZrO₂, SiO₂, and other suitable particles. A single type of insulative particle may be used or a plurality of types of insulative particles may be used in combination as the raw material insulative particles. It is preferable that the raw material insulative particles be Al₂O₃ particles, for example. When the raw material insulative particles are Al₂O₃ particles, it is possible to obtain an ESD protection device having superior ESD protection characteristics at a low cost. Note that in the present specification, the “raw material insulative particles being Al₂O₃ particles”, for example, means that Al₂O₃ is the primary component of the raw material insulative particles, and specifically means that the raw material insulative particles preferably have an Al₂O₃ content of greater than or equal to about 90 wt %, for example. The composition of the raw material insulative particles can be identified through a combination of qualitative analysis using XRD, and ICP-AES, for example.

### Application of Discharge Auxiliary Electrode Paste

The discharge auxiliary electrode paste is applied to the one main surface of the first ceramic green sheet in a predetermined pattern. The method of applying the discharge auxiliary electrode paste is not particularly limited, and a method such as screen printing can be selected as appropriate. The discharge auxiliary electrode paste applied to a ceramic green sheet will also be referred to as an “unfired discharge auxiliary electrode” hereinafter.

### Step (b)

Step (b) is a step of forming first and second unfired discharge electrodes by applying a discharge electrode paste to the first ceramic green sheet to which the discharge auxiliary electrode paste has been applied.

### Preparation of Discharge Electrode Paste

The discharge electrode paste for forming the discharge electrodes can be prepared through the following procedure. The discharge electrode paste is prepared by blending metal particles and/or alloy particles having a predetermined average particle diameter with an organic vehicle obtained by dissolving a binder such, as ethyl cellulose in an organic carrier, such as terpineol at a predetermined ratio, and then mixing using a three-roll mill or other suitable mixer. For example, Cu, Ni, Ag, Pd, and alloy thereof, or a combination of any of these may preferably be used as the metal particles and/or alloy particles, but the particles are not limited thereto.

### Application of Discharge Electrode Paste

The discharge electrode paste is applied in a predetermined pattern to the first ceramic green sheet to which the discharge auxiliary electrode paste has been applied. Hereinafter, the discharge electrode paste applied to the ceramic green sheet will also be called “unfired discharge electrodes” or a “first unfired discharge electrode” and a “second unfired discharge electrode”. The first and second unfired discharge electrodes are at least partially disposed upon the unfired discharge auxiliary electrode, and are disposed spaced apart from and opposed to each other upon the unfired discharge auxiliary electrode. At this time, a gap between the first unfired discharge electrode and the second unfired discharge electrode can be adjusted as appropriate so that the distance between discharge electrodes is a desired value in the obtained ESD protection device. The method of applying the discharge electrode paste is not particularly limited, and a method such as screen printing can be selected as appropriate.

### Step (c)

Step (c) is a step of applying a hollow cavity portion formation paste to the first ceramic green sheet to which the discharge auxiliary electrode paste and the discharge electrode paste have been applied.

### Preparation of Hollow Cavity Portion Formation Paste

The hollow cavity portion formation paste for forming the hollow cavity portion is prepared. A resin that breaks down and dissipates during firing may preferably be used as the hollow cavity portion formation paste, for example, polyethylene terephthalate (PET), polypropylene, ethyl cellulose, an acrylic resin, or other suitable resin may preferably be used. Specifically, the hollow cavity portion formation paste is prepared, for example, by blending crosslinked acrylic resin beads having a predetermined average particle diameter with an organic vehicle obtained by dissolving a binder, such as ethyl cellulose, in an organic carrier, such as terpineol, at a predetermined ratio, and then mixing using a three-roll mill or other suitable mixer.

### Application of Hollow Cavity Portion Formation Paste

The hollow cavity portion formation paste is applied in a predetermined pattern to the first ceramic green sheet to which the discharge auxiliary electrode paste and the discharge electrode paste have been applied. The hollow cavity portion formation paste is applied so as to cover at least the region where the first and second unfired discharge electrodes oppose each other. The method of applying the hollow cavity portion formation paste is not particularly limited, and a method such as screen printing can be selected as appropriate.

Note that where the above-described discharge auxiliary electrode paste, discharge electrode paste, and hollow cavity portion formation paste are each applied with relatively large thicknesses, the respective pastes may be applied so that a recess provided in advance in the first ceramic green sheet is sequentially filled by the respective pastes.

### Step (d)

Step (d) is a step of forming an unfired multilayer body by stacking a second ceramic green sheet on the first ceramic green sheet to which the discharge auxiliary electrode paste, the discharge electrode paste, and the hollow cavity portion formation paste have been applied and shaping the ceramic green sheets to predetermined dimensions. The first ceramic green sheet and the second ceramic green sheet may be the same type of sheet or different types of sheets. One or more other ceramic green sheets may be stacked above and/or below the first and second ceramic green sheets stacked in this manner. In this case, each of the stacked ceramic green sheets may be the same type of sheet, but two or more different types of ceramic green sheets may be combined as appropriate. The multilayer body obtained in this manner (also referred to as a mother multilayer body) is pressure bonded so that the overall thickness becomes a predetermined thickness. The pressure-bonded mother multilayer body is cut to predetermined dimensions using a microcutter or other suitable cutter to obtain the unfired multilayer body.

### Step (e)

Step (e) is a step of firing the unfired multilayer body to obtain a multilayer body including the insulative substrate, which is a ceramic substrate, the first and second discharge electrodes, the discharge auxiliary electrode, and the hollow cavity portion. The unfired multilayer body is preferably fired at about 900° C. to about 1,000° C. for approximately 90 minutes in a predetermined atmosphere, for example. The hollow cavity portion formation paste breaks down and vaporizes due to the firing, forming the hollow cavity portion as a result. The firing also breaks down and vaporizes the organic carrier and binder present in the ceramic green sheets and the respective pastes. It is preferable that step (e) be at least partially performed in an atmosphere including a noble gas, such as Ne or Ar, for example. Performing at least a portion of step (e) in an atmosphere including a noble gas makes it possible to obtain an ESD protection device in which the noble gas is present within the hollow cavity portion. Among noble gases, Ar ionizes comparatively easily and cheaply, and thus, it is preferable to use Ar as the noble gas.

Furthermore, it is preferable to perform step (e) in an atmosphere including H₂ and H₂O in addition to the noble gas, while maintaining an oxygen partial pressure P_{O2} at greater than or equal to an equilibrium oxygen partial pressure of C (carbon) and less than or equal to an equilibrium oxygen partial pressure of the metal particles included in the discharge electrode paste and the discharge auxiliary electrode paste, for example. Adjusting the atmosphere during firing in this manner induces the combustion of organic components present in the ceramic green sheet and the respective pastes while effectively reducing or preventing oxidization of the metal particles included in the discharge electrode paste and the discharge auxiliary electrode paste.

### Step (f)

Step (f) is a step of forming first and second unfired outer electrodes by applying an outer electrode paste to an outside surface of the fired multilayer body (chip).

### Preparation of Outer Electrode Paste

The outer electrode paste for forming the outer electrodes can be prepared through the following procedure. The outer electrode paste is prepared by blending Cu powder having a predetermined average particle diameter, borosilicate alkali glass frits having a predetermined transition point, softening point, and average particle diameter, and an organic vehicle obtained by dissolving a binder, such as ethyl cellulose, in an organic carrier, such as terpineol, at a predetermined ratio, and then mixing using a three-roll mill or other suitable mixer.

### Application of Outer Electrode Paste

The outer electrode paste is applied to both end portions of the chip by spreading or other suitable method. The outer electrode paste applied to the chip is also referred to as “unfired outer electrodes” or a “first unfired outer electrode” and a “second unfired outer electrode”. The first unfired outer electrode is formed so as to be in contact with the first discharge electrode, and the second unfired outer electrode is formed so as to be in contact with the second discharge electrode. By applying the outer electrode paste in this manner, the first outer electrode can be electrically connected to the first discharge electrode and the second outer electrode can be electrically connected to the second discharge electrode in the obtained ESD protection device.

### Step (g)

Step (g) is a step of forming the first and second outer electrodes by subjecting the unfired first and second outer electrodes to a baking process. The baking conditions can be adjusted as appropriate in accordance with the composition of the outer electrode paste and other factors and conditions. The surfaces of the outer electrodes that are formed may preferably be subjected to electrolytic Ni—Sn plating or other suitable plating process, for example.

The ESD protection device obtained in this manner has favorable initial insulative properties and has an favorable operation rate at a comparatively low discharge voltage of 2 kV.

### Method of Manufacturing ESD Protection Device According to Second Preferred Embodiment

A non-limiting method of manufacturing the ESD protection device according to the second preferred embodiment of the present invention will be described next. The following will be described with focus on the differences from the method of manufacturing the ESD protection device according to the first preferred embodiment, and unless otherwise stated, the descriptions provided for the method of manufacturing the ESD protection device according to the first preferred embodiment will apply here.

The discharge auxiliary electrode paste and the discharge electrode paste are applied to the first ceramic green sheet through the same procedures as in steps (a) and (b) in the method of manufacturing the ESD protection device according to the first preferred embodiment. The first ceramic green sheet may include a single layer, or may include a plurality of layers. Where the first ceramic green sheet includes a plurality of layers, each layer may have the same composition, or the layers may have different compositions. A multilayer body obtained in this manner (a mother multilayer body) is pressure bonded so that the overall thickness becomes a predetermined thickness. The pressure-bonded mother multilayer body is cut to predetermined dimensions using a microcutter or other suitable cutter to obtain the unfired multilayer body. The unfired multilayer body is then fired to obtain a multilayer body including the insulative substrate, which is a ceramic substrate, the first and second discharge electrodes, and the discharge auxiliary electrode. The outer electrodes are formed on an outside surface of this multilayer body (chip) through the same procedures as in the above-described steps (f) and (g). The top of the multilayer body may then be covered with a resin layer using a known method.

Although the foregoing has described a method of manufacturing an ESD protection device including a single pair of discharge electrodes (the first and second discharge electrodes), an ESD protection device including two or more pairs of discharge electrodes can be manufactured as appropriate based on the above-described manufacturing method.

### WORKING EXAMPLES

With respect to the ESD protection device according to the first preferred embodiment of the present invention, Examples 1 to 19 of the ESD protection device were manufactured through the following procedures.

### Preparation of Ceramic Green Sheet

Toluene and Ekinen (registered trademark) were added to a powder of a ceramic material including Ba, Al, and Si as primary components (BAS), which were then mixed. A binder resin and a plasticizer were further added to this mixture and mixed to obtain a ceramic slurry. The ceramic slurry was shaped through a doctor blade method, and a 50 μm-thick ceramic green sheet was obtained.

### Preparation of Discharge Auxiliary Electrode Paste

The metal particles, semiconductor particles, insulative particles, and organic vehicles indicated in the following Table 1 were prepared.

TABLE 1

| METAL | PRIMARY | AVG. PARTICLE |
|---|---|---|
| PARTICLES | COMPONENT | DIAMETER (μm) |
| M-1 | Cu | 0.10 |
| M-2 | Cu | 0.30 |
| M-3 | Cu | 1.00 |
| M-4 | Cu | 1.50 |
| SEMICONDUCTOR | PRIMARY | SPECIFIC SURFACE |
| PARTICLES | COMPONENT | AREA (m²/g) |
| S-1 | SiC | 15 |
| S-2 | SiC | 12 |
| S-3 | SiC | 7 |
| S-4 | SiC | 3 |
| INSULATIVE | PRIMARY | SPECIFIC SURFACE |
| PARTICLES | COMPONENT | AREA (m²/g) |
| I-1 | Al₂O₃ | 20 |
| | COMPOSITION (VOL %) | |
| ORGANIC VEHICLE | ETHYL CELLULOSE | TERPINEOL |
| V-1 | 12.75 | 87.25 |

The composition of the metal particles was analyzed through ICP-AES (inductively coupled plasma atomic emission spectroscopy) and inert gas fusion using an oxygen/nitrogen analyzer (Horiba, Ltd.), and it was confirmed that the Cu content was greater than or equal to about 90 wt %, or in other words, that Cu was the primary component of the metal particles.

The average particle diameter of the metal particles (Cu particles) was determined through the following procedure. First, an SEM image (10,000×) of the metal particles was captured, a single diagonal line was drawn from the apex of the obtained image, and the lengths of the long sides of all of the metal particles intersecting with the diagonal line were measured. This operation was performed for five SEM images captured in different regions, and an average value of the measured lengths of the long sides of the metal particles was calculated. The average value calculated in this manner was taken as the average particle diameter of the metal particles.

After confirming that SiC crystals were present through qualitative analysis using XRD (X-ray diffractometer), the composition of the semiconductor particles was analyzed through ICP-AES and oxygen flow combustion high-frequency furnace-based infrared absorption using a carbon/sulfur analyzer (Horiba, Ltd.), and an SiC content of greater than or equal to about 90 wt % was confirmed.

After confirming that Al₂O₃ crystals were present through qualitative analysis using XRD, the composition of the insulative particles was analyzed through ICP-AES, and an Al₂O₃ content of greater than or equal to about 90 wt % was confirmed.

The specific surface areas of the semiconductor particles (SiC particles) and the insulative particles (Al₂O₃ particles) were measured through singlepoint BET using nitrogen gas.

Mixtures of the metal particles, semiconductor particles, insulative particles, and organic vehicle indicated in Table 1 were dispersed and mixed at the ratios indicated in the following Table 2 using a three-roll mill, and discharge auxiliary electrode pastes P-1 to P-15 were prepared.

TABLE 2

| | | | | | | | | | RATIO OF METAL |
|---|---|---|---|---|---|---|---|---|---|
| | COMPOSITION (VOL %) | | | | | | | | PARTICLES IN |
| | NON-COMBUSTIBLE COMPONENTS | | | | | | | | NON-COMBUSTIBLE |
| | METAL | | SEMICONDUCTOR | | INSULATIVE | | ORGANIC | | COMPONENTS |
| NO. | PARTICLES | | PARTICLES | | PARTICLES | | VEHICLE | | (VOL %) |
| P-1 | M-2 | 1.50 | S-2 | 13.50 | — | — | V-1 | 85.00 | 10 |
| P-2 | ↑ | 2.25 | ↑ | 12.75 | — | — | ↑ | 85.00 | 15 |
| P-3 | ↑ | 4.50 | ↑ | 10.50 | — | — | ↑ | 85.00 | 30 |
| P-4 | ↑ | 6.00 | ↑ | 9.00 | — | — | ↑ | 85.00 | 40 |
| P-5 | ↑ | 6.75 | ↑ | 8.25 | — | — | ↑ | 85.00 | 45 |
| P-6 | ↑ | 4.50 | S-1 | 10.50 | — | — | ↑ | 85.00 | 30 |
| P-7 | ↑ | 4.50 | S-3 | 10.50 | — | — | ↑ | 85.00 | 30 |
| P-8 | ↑ | 4.50 | S-4 | 10.50 | — | — | ↑ | 85.00 | 30 |
| P-9 | ↑ | 4.50 | S-2 | 9.75 | I-1 | 0.75 | ↑ | 85.00 | 30 |
| P-10 | ↑ | 4.50 | ↑ | 6.00 | ↑ | 4.50 | ↑ | 85.00 | 30 |
| P-11 | M-1 | 2.25 | ↑ | 12.75 | — | — | ↑ | 85.00 | 15 |
| P-12 | M-3 | 6.00 | ↑ | 9.00 | — | — | ↑ | 85.00 | 40 |
| P-13 | M-4 | 2.25 | ↑ | 12.75 | — | — | ↑ | 85.00 | 15 |
| P-14 | ↑ | 6.00 | ↑ | 9.00 | — | — | ↑ | 85.00 | 40 |
| P-15 | ↑ | 6.00 | ↑ | 4.50 | I-1 | 4.50 | ↑ | 85.00 | 40 |

### Preparation of Discharge Electrode Paste

The discharge electrode paste was prepared by mixing Cu powder having an average particle diameter of about 1 μm at about 40 wt %, Cu powder having an average particle diameter of about 3 μm at about 40 wt %, and an organic vehicle at about 20 wt %. Note that the organic vehicle used in the preparation of the discharge electrode paste was a vehicle prepared by dissolving ethyl cellulose in terpineol, and the ethyl cellulose content in the organic vehicle was about 10 wt %.

### Preparation of Hollow Cavity Portion Formation Paste

The hollow cavity portion formation paste was prepared by proportioning and mixing crosslinked acrylic resin beads having an average particle diameter of 1 μm at about 38 wt %, and about 62 wt % of an organic vehicle in which about 10 wt % of ethocel resin was dissolved in terpineol.

### Preparation of Outer Electrode Paste

The outer electrode paste was prepared by proportioning and milling Cu powder having an average particle diameter of about 1 μm at about 80 wt %, borosilicate alkali glass frits having a transition point of about 620° C., a softening point of about 720° C., and an average particle diameter of about 1 μm at about 5 wt %, and an organic vehicle in which acrylic resin was dissolved in terpineol at about 15 wt %. The acrylic resin content in the organic vehicle was about 20 wt %.

The ESD protection devices according to Examples 1 to 19 were manufactured through the procedures described below using the ceramic green sheets, the discharge auxiliary electrode paste, the discharge electrode paste, the hollow cavity portion formation paste, and the outer electrode paste prepared in this manner. The ESD protection devices according to Examples 1 to 19 have the same or substantially the same structures as illustrated in FIGS. 1 and 2.

### Example 1

### Step (a)

The P-1 discharge auxiliary electrode paste was applied to the ceramic green sheet in a shape corresponding to the discharge auxiliary electrode.

### Step (b)

Next, the discharge electrode paste was applied in a shape in which a pair of discharge electrode pastes oppose each other in the length direction on the discharge auxiliary electrode paste. The distance between the opposing pair of discharge electrode pastes (the first and second unfired discharge electrodes) was set to about 24 μm.

### Step (c)

Next, the hollow cavity portion formation paste was applied so as to cover the opposing portions of the discharge electrode pastes.

### Step (d)

A new ceramic green sheet was stacked upon the ceramic green sheet on which the discharge auxiliary electrode paste, the discharge electrode pastes, and the hollow cavity portion formation paste were applied in this manner, a plurality of new ceramic green sheets were further stacked thereabove and therebelow, and the ceramic green sheets were then pressure-bonded to obtain a mother multilayer body having a thickness of about 0.3 mm. The mother multilayer body was cut in the thickness direction so as to have a about 1.0 mm×about 0.5 mm rectangular planar shape, thus producing chips corresponding to individual ESD protection device units. The dimensions of the obtained chip (unfired multilayer body) were about 1.0 mm (length L)×0.5 mm (width W)×about 0.3 mm (thickness T).

### Step (e)

The chip obtained in step (d) was then fired in a N₂/H₂/H₂O atmosphere while maintaining the oxygen partial pressure P_{O2} greater than or equal to the equilibrium oxygen partial pressure of C (carbon) and less than or equal to the equilibrium oxygen partial pressure of Cu.

### Step (f)

The outer electrode paste was applied to both end portions of the fired chip. The outer electrode paste was applied to both end portions of the chip so as to make contact with the first and second discharge electrodes, respectively, within the chip.

### Step (g)

The first and second outer electrodes were formed by baking the outer electrode paste applied to both end portions of the chip. The ESD protection device according to Example 1 was obtained in this manner.

### Examples 2 to 15

The ESD protection devices according to Examples 2 to 15 were manufactured using the same procedure as in Example 1, with the exception of P2 to 15 being used for the discharge auxiliary electrode paste instead of P-1.

### Example 16

The ESD protection device according to Example 16 was manufactured using the same procedure as for Example 3, except that step (e) was carried out in an Ar/H₂/H₂O atmosphere.

### Example 17

The ESD protection device according to Example 17 was manufactured using the same procedure as for Example 9, except that step (e) was carried out in an Ar/H₂/H₂O atmosphere.

### Example 18

The ESD protection device according to Example 18 was manufactured using the same procedure as for Example 3, except that the distance between the unfired discharge electrodes was set to about 12 μm.

### Example 19

The ESD protection device according to Example 19 was manufactured using the same procedure as for Example 3, except that the distance between the unfired discharge electrodes was set to about 60 μm.

The manufacturing conditions of the ESD protection devices according to Examples 1 to 19 are indicated in the following Table 3.

TABLE 3

| | | DISTANCE | |
|---|---|---|---|
| | DISCHARGE | BETWEEN | |
| | AUXILIARY | UNFIRED | |
| | ELECTRODE | DISCHARGE | FIRING |
| EXAMPLE | PASTE | ELECTRODES (μm) | ATMOSPHERE |
| 1 | P-1 | 24 | N₂/H₂/H₂O |
| 2 | P-2 | 24 | N₂/H₂/H₂O |
| 3 | P-3 | 24 | N₂/H₂/H₂O |
| 4 | P-4 | 24 | N₂/H₂/H₂O |
| 5 | P-5 | 24 | N₂/H₂/H₂O |
| 6 | P-6 | 24 | N₂/H₂/H₂O |
| 7 | P-7 | 24 | N₂/H₂/H₂O |
| 8 | P-8 | 24 | N₂/H₂/H₂O |
| 9 | P-9 | 24 | N₂/H₂/H₂O |
| 10 | P-10 | 24 | N₂/H₂/H₂O |
| 11 | P-11 | 24 | N₂/H₂/H₂O |
| 12 | P-12 | 24 | N₂/H₂/H₂O |
| 13 | P-13 | 24 | N₂/H₂/H₂O |
| 14 | P-14 | 24 | N₂/H₂/H₂O |
| 15 | P-15 | 24 | N₂/H₂/H₂O |
| 16 | P-3 | 24 | Ar/H₂/H₂O |
| 17 | P-9 | 24 | Ar/H₂/H₂O |
| 18 | P-3 | 12 | N₂/H₂/H₂O |
| 19 | P-3 | 60 | N₂/H₂/H₂O |

The obtained ESD protection devices according to Examples 1 to 19 were subjected to the following structural analyses.

### Distance Between Discharge Electrodes

The ESD protection device was polished in the direction of the LW plane (a plane perpendicular to the thickness direction) so as to expose the first and second discharge electrodes and the discharge auxiliary electrode. The distance between the exposed first discharge electrode and second discharge electrode was measured using a microscope. This process was performed on ten ESD protection devices according to each example, and an average value of the measured distances was determined. This average value was taken as the “distance between discharge electrodes”.

### Constituent Components of Discharge Auxiliary Electrode

The ESD protection device was polished in the direction of the LW plane so as to expose the first and second discharge electrodes and the discharge auxiliary electrode. The exposed discharge auxiliary electrode was subjected to microfocus X-ray analysis, and the constituent components of the discharge auxiliary electrode were identified from the peaks obtained as a result.

### Average Particle Diameter of Metal Particles in Discharge Auxiliary Electrode

The ESD protection device was polished in the direction of the LT plane (the plane perpendicular to the width direction) to a ½ W point (a point approximately halfway along the width dimension of the ESD protection device) so as to expose a cross-section of the discharge auxiliary electrode. An SEM image of the exposed discharge auxiliary electrode part was captured (a reflection electron image; 10,000×), and of the metal particles appearing in the obtained image, the lengths of the long sides of particles located entirely within the image were measured. This process was performed on ten ESD protection devices according to each example, and an average value of the measured lengths of the long sides was determined. This average value was taken as the “average particle diameter of metal particles” in the discharge auxiliary electrode.

### Density of Metal Particles in Discharge Auxiliary Electrode

The ESD protection device was polished in the direction of the LT plane to the ½ W point so as to expose a cross-section of the discharge auxiliary electrode. An SEM image of the exposed discharge auxiliary electrode was captured (a reflection electron image; 10,000×), and the total number of metal particles present in a 50 μm² surface area range of the discharge auxiliary electrode was counted in the obtained image. This process was performed on ten ESD protection devices according to each example, and an average value of the total number of metal particles was determined. This average value was taken as the “density of metal particles” in the discharge auxiliary electrode.

### Primary Components of Gas Present in Hollow Cavity Portion

The primary components of the gas present in the hollow cavity portion were measured through the following procedure. 20 ESD protection devices according to each example were prepared. The ESD protection devices were fractured within a vacuum, and the components present in the gas produced were analyzed using a mass spectrometer (MS) to identify the primary components of the gas present in the hollow cavity portion.

The structural analysis results of the ESD protection devices according to Examples 1 to 19 are indicated in the following Table 4.

TABLE 4

| | | CONSTITUENT | AVG. | | PRIMARY |
|---|---|---|---|---|---|
| | DISTANCE | COMPONENTS | PARTICLE | DENSITY OF | COMPONENT |
| | BETWEEN | OF | DIAMETER | METAL | OF GAS IN |
| | DISCHARGE | DISCHARGE | OF METAL | PARTICLES | HOLLOW |
| | ELECTRODES | AUXILIARY | PARTICLES | (PARTICLES/50 | CAVITY |
| EXAMPLE | (μm) | ELECTRODE | (μm) | (μm²) | PORTION |
| 1 | 20 | Cu, SiC | 0.85 | 10 | N₂ |
| 2 | 20 | Cu, SiC | 0.85 | 20 | N₂ |
| 3 | 20 | Cu, SiC | 0.85 | 30 | N₂ |
| 4 | 20 | Cu, SiC | 0.94 | 33 | N₂ |
| 5 | 20 | Cu, SiC | 1.70 | 40 | N₂ |
| 6 | 20 | Cu, SiC | 0.85 | 30 | N₂ |
| 7 | 20 | Cu, SiC | 0.85 | 30 | N₂ |
| 8 | 20 | Cu, SiC | 0.85 | 30 | N₂ |
| 9 | 20 | Cu, SiC, Al₂O₃ | 0.73 | 40 | N₂ |
| 10 | 20 | Cu, SiC, Al₂O₃ | 0.66 | 55 | N₂ |
| 11 | 20 | Cu, SiC | 0.30 | 170 | N₂ |
| 12 | 20 | Cu, SiC | 1.50 | 25 | N₂ |
| 13 | 20 | Cu, SiC | 1.50 | 15 | N₂ |
| 14 | 20 | Cu, SiC | 2.20 | 21 | N₂ |
| 15 | 20 | Cu, SiC | 1.70 | 32 | N₂ |
| 16 | 20 | Cu, SiC | 0.85 | 30 | Ar |
| 17 | 20 | Cu, SiC | 0.73 | 40 | Ar |
| 18 | 10 | Cu, SiC | 0.85 | 30 | N₂ |
| 19 | 50 | Cu, SiC | 0.85 | 30 | N₂ |

Comparing Examples 1 to 5, it can be seen that as the ratio of metal particles within the non-combustible components included in the discharge auxiliary electrode paste increases, the average particle diameter of the metal particles within the discharge auxiliary electrode in the obtained ESD protection device tends to increase. Such a trend can also be confirmed by comparing Examples 13 and 14. These trends arise due to the metal particles sintering with each other more easily in the firing of step (e) as the ratio of metal particles within the non-combustible components increases. Additionally, comparing Examples 1 to 5, it can be seen that as the ratio of metal particles within the non-combustible components included in the discharge auxiliary electrode paste increases, the density of the metal particles within the discharge auxiliary electrode in the obtained ESD protection device increases. This trend can also be confirmed by comparing Examples 13 and 14.

Comparing Examples 3 and 6 to 8, it can be seen that where the specific surface area of the semiconductor particles included in the discharge auxiliary electrode paste is about 3 m²/g to about 15 m²/g, the average particle diameter and density of the metal particles within the discharge auxiliary electrode in the obtained ESD protection device have the same values.

Comparing Examples 3 and 9, it can be seen that when insulative particles are added to the discharge auxiliary electrode paste, the average particle diameter of the metal particles within the discharge auxiliary electrode in the obtained ESD protection device decreases and the density of the metal particles increases. This occurs because adding insulative particles to the discharge auxiliary electrode paste prevents the metal particles from sintering with each other during the firing in step (e). Such a trend can also be confirmed by comparing Examples 14 and 15. Furthermore, comparing Examples 9 and 10, it can be seen that when the amount of insulative particles added is increased, the average particle diameter of the metal particles within the discharge auxiliary electrode in the obtained ESD protection device further decreases and the density of the metal particles further increases.

Comparing Examples 2, 11, and 13, it can be seen that as the average particle diameter of metal particles included in the discharge auxiliary electrode paste increases, the average particle diameter of the metal particles within the discharge auxiliary electrode in the obtained ESD protection device increases and the density of the metal particles increases. Such a trend can also be confirmed by comparing Examples 4, 12, and 14.

Comparing Examples 3, 9, 16, and 17, it can be seen that even where the atmosphere for the firing of step (e) is changed, the average particle diameter and density of the metal particles within the discharge auxiliary electrode in the obtained ESD protection device do not change.

Comparing Examples 3, 18, and 19, it can be seen that adjusting the distance between the unfired discharge electrodes formed by applying the discharge electrode paste enables the distance between discharge electrodes in the obtained ESD protection device to be changed.

Next, the ESD protection characteristics indicated below were evaluated using the ESD protection devices according to Examples 1 to 19.

### Initial Insulative Properties

A voltage of about 15 V was applied between the outer electrodes of the ESD protection device, and a resistance value (IR) between the outer electrodes was measured. This process was performed on 100 ESD protection devices according to each example, and an average value of the resistance values was determined. An average resistance value of log IR≧7 was evaluated as “good (O)” initial insulative properties, and an average resistance value of log IR<7 was evaluated as “poor (x)” initial insulative properties. The results are indicated in Table 5. ESD protection devices evaluated as having “poor (X)” initial insulative properties are unsuitable for practical applications, and thus, were not subjected to the 2 kV operation rate evaluation described next.

Operation Rate at about 2 kV

The operation rate at about 2 kV was evaluated through contact discharge based on the IEC 61000-4-2 standard defined by the International Electrotechnical Commission (IEC). A voltage of about 2 kV was applied between the outer electrodes of the ESD protection device, a peak voltage value (Vₚₑₐₖ) was measured, and it was determined that a discharge had started between the discharge electrodes, or in other words, that the ESD protection device had operated, in the case where Vₚₑₐₖ≦500 V. This process was performed for 100 ESD protection devices according to each example, and the percentage of the 100 ESD protection devices for which discharges started was taken as the operation rate (%) at about 2 kV. Devices having an operation rate at about 2 kV of 100% were evaluated as “very good (⊙)”, greater than or equal to 90% and less than 100% as “good (◯)”, greater than or equal to 70% and less than 90% as “fair (Δ)”, and less than 70% as “poor (x)”. The results are indicated in Table 5. Note that ESD protection devices determined as “x” are considered to be unsuitable for practical applications.

TABLE 5

| | INITIAL | OPERATION |
|---|---|---|
| | INSULATIVE | RATE AT |
| EXAMPLE | PROPERTIES | 2 kV |
| 1 | ◯ | X |
| 2 | ◯ | Δ |
| 3 | ◯ | Δ |
| 4 | ◯ | Δ |
| 5 | X | — |
| 6 | ◯ | Δ |
| 7 | ◯ | Δ |
| 8 | ◯ | Δ |
| 9 | ◯ | ◯ |
| 10 | ◯ | ⊙ |
| 11 | ◯ | ⊙ |
| 12 | ◯ | Δ |
| 13 | ◯ | X |
| 14 | X | — |
| 15 | ◯ | X |
| 16 | ◯ | ◯ |
| 17 | ◯ | ⊙ |
| 18 | ◯ | Δ |
| 19 | ◯ | Δ |

As indicated in Table 5, the ESD protection devices according to Examples 1 to 4, 6 to 13, and 15 to 19 showed favorable initial insulative properties. On the other hand, the ESD protection devices according to Examples 5 and 14 showed initial insulative properties unsuitable for practical applications. Comparing Examples 1 to 4 with Example 5, it can be seen that when the volume fraction of metal particles relative to all non-combustible components within the discharge auxiliary electrode paste exceeds about 40 vol %, the average particle diameter of the metal particles present within the discharge auxiliary electrode in the obtained ESD protection device becomes greater than about 1.5 μm, and the initial insulative properties deteriorate as a result. Meanwhile, comparing Examples 4 and 12 with Example 14, it can be seen that when the average particle diameter of the metal particles within the discharge auxiliary electrode paste exceeds about 1.0 μm, the average particle diameter of the metal particles present within the discharge auxiliary electrode in the obtained ESD protection device becomes greater than about 1.5 μm, and the initial insulative properties deteriorate as a result.

As indicated in Table 5, the ESD protection devices according to Examples 2 to 4, 6 to 12, and 16 to 19 exhibited operation rates suitable for practical applications at about 2 kV. On the other hand, the ESD protection devices according to Examples 1, 13, and 15 exhibited operation rates not suitable for practical applications at about 2 kV. Comparing Example 1 with Examples 2 to 4, it can be seen that when the volume fraction of the metal particles relative to all the non-combustible components within the discharge auxiliary electrode paste is lower than about 15 vol %, the density of the metal particles present within the discharge auxiliary electrode in the obtained ESD protection device becomes lower than about 20 particles/50 μm², and the operation rate at about 2 kV drops as a result.

Comparing Example 3 and 6 to 8, it can be seen that where the specific surface area of the semiconductor particles included in the discharge auxiliary electrode paste is about 3 m²/g to about 15 m²/g, the same operation rate is obtained at about 2 kV.

Comparing Examples 3 and 9, it can be seen that when insulative particles are added to the discharge auxiliary electrode paste, the average particle diameter of the metal particles within the discharge auxiliary electrode in the obtained ESD protection device decreases and the density of the metal particles increases, and the operation rate at about 2 kV is improved as a result. Furthermore, comparing Examples 9 and 10, it can be seen that increasing the amount of insulative particles added further improves the operation rate at about 2 kV.

Comparing Examples 2, 11, and 12, it can be seen that reducing the average particle diameter of the metal particles included in the discharge auxiliary electrode paste and increasing the volume fraction of the metal particles relative to all non-combustible components within the discharge auxiliary electrode paste further reduces the average particle diameter of the metal particles within the discharge auxiliary electrode in the obtained ESD protection device and further increase the density of the metal particles, and an extremely favorable operation rate can be achieved at about 2 kV as a result.

Based on Example 13, it can be seen that when the average particle diameter of the metal particles included in the discharge auxiliary electrode paste exceeds about 1.0 μm and the volume fraction of the metal particles relative to all non-combustible components within the discharge auxiliary electrode paste is comparatively low, the density of the metal particles within the discharge auxiliary electrode in the obtained ESD protection device becomes less than about 20 particles/50 μm², and the operation rate at about 2 kV drops as a result. Additionally, based on Example 15, it can be seen that when the average particle diameter of the metal particles included in the discharge auxiliary electrode paste exceeds about 1.0 μm and the volume fraction of the metal particles relative to all non-combustible components within the discharge auxiliary electrode paste is comparatively high, the average particle diameter of the metal particles within the discharge auxiliary electrode in the obtained ESD protection device becomes greater than about 1.5 μm, and the operation rate at about 2 kV drops as a result.

Comparing Examples 3 and 9 with Examples 16 and 17, it can be seen that an ESD protection device in which the hollow cavity portion includes Ar gas as a primary component further improves the operation rate at about 2 kV compared to an ESD protection device in which the hollow cavity portion includes N₂ gas as a primary component.

Based on Examples 3, 18, and 19, it can be seen that even where the distance between discharge electrodes is changed, the same initial insulative properties and the same operation rate at about 2 kV are achieved.

ESD protection devices according to preferred embodiments of the present invention achieve favorable ESD protection characteristics, and therefore effectively prevent damage and erroneous operations in electronic devices caused by ESD.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electrostatic discharge protection device comprising:
an insulative substrate;
first and second discharge electrodes disposed in contact with the insulative substrate, the first and second discharge electrodes being disposed spaced apart from and opposed to each other;
first and second outer electrodes provided on an outside surface of the insulative substrate, the first outer electrode being electrically connected to the first discharge electrode, and the second outer electrode being electrically connected to the second discharge electrode; and
a discharge auxiliary electrode extending from the first discharge electrode to the second discharge electrode in a region where the first and second discharge electrodes oppose each other; wherein
the discharge auxiliary electrode includes at least semiconductor particles and metal particles, with an average particle diameter of the metal particles being about 0.3 μm to 1.5 μm and a density of the metal particles at a random cross-section of the discharge auxiliary electrode being greater than or equal to about 20 particles/50 μm².

2. The electrostatic discharge protection device according to claim 1, wherein the insulative substrate is a ceramic substrate.

3. The electrostatic discharge protection device according to claim 1, wherein the insulative substrate is a resin substrate.

4. The electrostatic discharge protection device according to claim 1, wherein the semiconductor particles are SiC particles.

5. The electrostatic discharge protection device according to claim 1, wherein the metal particles are Cu particles.

6. The electrostatic discharge protection device according to claim 1, wherein the discharge auxiliary electrode further includes insulative particles.

7. The electrostatic discharge protection device according to claim 6, wherein the insulative particles are Al₂O₃ particles.

8. The electrostatic discharge protection device according to claim 1, wherein a distance between the first and second discharge electrodes at a region where the first and second discharge electrodes oppose each other is about 10 μm to about 50 μm.

9. The electrostatic discharge protection device according to claim 1, wherein the first and second discharge electrodes are disposed within the insulative substrate, and the first and second discharge electrodes are spaced apart from and opposed to each other within a hollow cavity portion provided within the insulative substrate.

10. The electrostatic discharge protection device according to claim 9, wherein the hollow cavity portion includes a noble gas.

11. The electrostatic discharge protection device according to claim 11, wherein the noble gas is Ar.

12. The electrostatic discharge protection device according to claim 1, wherein the first and second discharge electrodes are disposed on an outside surface of the insulative substrate.

13. A method of manufacturing an electrostatic discharge protection device, the method comprising:
a step (a) of forming an unfired discharge auxiliary electrode by applying a discharge auxiliary electrode paste including metal particles, semiconductor particles, and an organic vehicle to one main surface of a first ceramic green sheet, an average particle diameter of the metal particles being about 0.10 μm to about 1.00 μm and a volume fraction of the metal particles relative to all non-combustible components including the metal particles and the semiconductor particles being about 15 vol % to about 40 vol %;
a step (b) of forming first and second unfired discharge electrodes by applying a discharge electrode paste on the first ceramic green sheet to which the discharge auxiliary electrode paste has been applied, the first and second unfired discharge electrodes being at least partially disposed on the unfired discharge auxiliary electrode and being spaced apart from and opposed to each other on the unfired discharge auxiliary electrode;
a step (c) of applying a hollow cavity portion formation paste on the first ceramic green sheet to which the discharge auxiliary electrode paste and the discharge electrode paste have been applied, the hollow cavity portion formation paste being applied so as to cover at least a region where the first and second unfired discharge electrodes oppose each other;
a step (d) of forming an unfired multilayer body by stacking a second ceramic green sheet on the first ceramic green sheet to which the discharge auxiliary electrode paste, the discharge electrode paste, and the hollow cavity portion formation paste have been applied and shaping the ceramic green sheets to predetermined dimensions;
a step (e) of firing the unfired multilayer body to obtain a multilayer body including the ceramic substrate, the first and second discharge electrodes, the discharge auxiliary electrode, and the hollow cavity portion;
a step (f) of forming first and second unfired outer electrodes by applying an outer electrode paste to an outside surface of the fired multilayer body, the first unfired outer electrode being formed in contact with the first discharge electrode and the second unfired outer electrode being formed in contact with the second discharge electrode; and
a step (g) of forming first and second outer electrodes by subjecting the unfired first and second outer electrodes to a baking process.

14. The method according to claim 13, wherein a specific surface area of the semiconductor particles is greater than or equal to about 3 m²/g.

15. The method according to claim 13, wherein the semiconductor particles are a pulverized product.

16. The method according to claim 13, wherein the semiconductor particles are SiC particles.

17. The method according to claim 13, wherein an average particle diameter of the metal particles is about 0.10 μm to about 1.00 μm.

18. The method according to claim 13, wherein the metal particles are Cu particles.

19. The method according to claim 13, wherein the discharge auxiliary electrode paste further includes insulative particles, and in the discharge auxiliary electrode paste, a volume fraction of the metal particles relative to all non-combustible components including the metal particles, the semiconductor particles, and the insulative particles is about 15 vol % to about 40 vol %.

20. The method according to claim 19, wherein a specific surface area of the insulative particles is greater than or equal to about 20 m²/g.

21. The method according to claim 19, wherein the insulative particles are Al₂O₃ particles.

22. The method according to claim 13, wherein step (e) is at least partially performed in an atmosphere including a noble gas.

23. The method according to claim 22, wherein the noble gas is Ar.
